(19) United States
(12) Patent Application Publication
(10) Pub. No.: US 2026/0333604 A1
(43) Pub. Date: Oct. 22, 2026

(54) CLAMPING MECHANSIM FOR RELEASABLY SECURING RISER CARD ASSEMBLY

(71) Applicant: Aivres Systems Inc., San Jose, CA (US)

(72) Inventor: Mingli TSAI, New Taipei City (TW)

(21) Appl. No.: 19/183,321

(22) Filed: Apr. 18, 2025

(51) Int. Cl. H05K 7/14

(52) U.S. Cl. CPC H05K 7/1401; H05K 7/1429

(57) ABSTRACT

A riser card assembly can connect one or more expansion cards through a common riser card to a board-mounted expansion socket on a motherboard that defines an installation direction. The riser card assembly includes a card bracket having a card supporting brace extending in a longitudinal direction and a clamping mechanism operative attached to the card supporting brace. The clamping mechanism includes a pushrod extending in the installation direction and a movable retainer movable with respect to the card supporting brace in the longitudinal direction. During installation, the pushrod is displaced against the motherboard to move the movable retainer in the longitudinal direction adjacent to the expansion cards.

### TECHNICAL FIELD

This patent application relates to components for computing systems and, in particular, to a clamping mechanism to releasably restrain expansion cards within the chassis.

### BACKGROUND

Many computer systems, and particularly servers communicatively connected to a computer network to provide functionality and resources for other systems, are modularly designed for flexibility and scalability. For example, conventional computer systems include a motherboard or mainboard on which core computing components such as processors and main memory are mounted and are electronically interconnected. The motherboard is planar and is typically positioned horizontally within the chassis of the computer system.

To add additional functionality, one or more special purpose add-in cards or expansion cards can be electrically connected to the motherboard to interact with the core components. For example, the expansion cards can be designed to provide additional processing capabilities such as a graphics processing unit, increase data storage, and modify or improve networking capabilities and communications. To facilitate adaptability and modularity, motherboards typically include one or more board-mounted expansion sockets that are often configured as edge connectors having an elongated slot that receives the boarder or edge of an expansion card on which conductive traces are exposed.

When the expansion cards are connected perpendicularly to the board-mounted expansion sockets on the motherboard, the expansion cards will project vertically upwards in the chassis. The height dimensions of the chassis are limited, as may occur if the computer system is a data server or a network server intended to be accommodated in a vertical rack, and the chassis may not be able to accommodate larger expansion cards having a desired surface area. Moreover, if the computer system is functioning as a server, it may be desired to add more expansion cards to the computer system than there are a corresponding number of board-mounted expansion sockets on the motherboard.

To address the space and capacity constraints, riser cards may be used to function as an intermediate connector between the expansion cards and the motherboard, allowing the expansion cards and mother board to be indirectly connected. The riser card may be planar and shorter than the corresponding expansion cards and may include a plurality of card-mounted expansion sockets oriented horizontally to receive the expansion cards. The expansion cards therefore extend parallel to the planar orientation of the motherboard, which allows larger or longer expansion cards to be used.

Because both the board-mounted expansion sockets and the card-mounted expansion sockets are edge connectors that support only a single contact edge of the printed circuit card that is connected thereto, the computer system can include additional supports and bracing to stabilize the arrangement of riser card and expansion cards. For example, a riser card bracket can be attached to the riser card and the expansion cards to stabilize and prevent undesired movement within the chassis of the computer system.

### SUMMARY OF THE DISCLOSURE

To securely install a riser card assembly within a computer system, the disclosure provides a card bracket including an I/O panel brace and card supporting brace intersecting at a right angle. The card bracket can accommodate an expansion card stack including a plurality of expansion cards, each having a front I/O edge adjacent to the I/O panel brace and a rear card edge spaced apart from the front I/O edge in a longitudinal direction. To secure the expansion card stack, a clamping mechanism is operatively associated with the card bracket. The clamping mechanism includes a pushrod extending beyond the card bracket in an installation direction of the riser card assembly and a movable retainer configured to move in the longitudinal direction adjacent to the rear card edges upon displacement of the pushrod in the installation direction.

In a further aspect, the longitudinal direction and the installation direction are orthogonal.

In a further aspect, the clamping mechanism comprises a bell crank for redirecting displacement of the pushrod in the installation direction to movement of the movable retainer in the longitudinal direction.

In a further aspect, the clamping mechanism is spring-loaded and comprises a coil spring biasing the bell crank to move the movable retainer longitudinally away from the rear card edges of the expansion card.

In a further aspect, the bell crank is rotatably attached to the card supporting brace to rotate with respect to a crank axis that is orthogonal to the installation direction and the longitudinal direction.

In a further aspect, the bell crank comprises a first crank arm and a second crank arm that angularly diverge from each other with respect to the crank axis.

In a further aspect, the first crank arm is connected to the pushrod by a pin-and-slot joint.

In a further aspect, the second crank arm is connected to the movable retainer by a translating joint.

In a further aspect, the translating joint comprises a crank pin on the second crank arm that can be retained in a bifurcated catch on the movable retainer.

In a further aspect, the clamping mechanism comprises a frame plate fixedly attached to the card supporting brace such that the movable retainer moves with respect to the frame plate.

In a further aspect, the crank axis is perpendicular to the frame plate.

In a further aspect, the movable retainer comprises one or more retainer stanchions that extend from a retainer base in a lateral direction parallel to the crank axis.

In a further aspect, the plurality of expansion cards are each associated with a card retention tail that is configured to releasably engage with a respective one of the retainer stanchion

The disclosure also provides a method of installing a riser card assembly to a board-mounted connector socket on a mother board in a computer system. The method includes attaching a riser card to a card supporting brace of a card bracket that extends in a longitudinal direction. The riser card may have a riser contact edge directed in an installation direction orthogonal to the longitudinal direction. One or more expansion cards are connected to the riser card and oriented orthogonal to the longitudinal direction and to the installation direction.

To install the riser card assembly to the board-mounted expansion socket, the riser card assembly is moved in the installation direction toward the motherboard. The motherboard can concurrently displace a pushrod of a clamping mechanism associated with the card bracket in the installation direction. The pushrod is operatively connected through a bell crank to linearly move the movable retainer in the longitudinal direction and adjacent to the rear card edges of the expansion cards to clamp the expansion cards to the card bracket.

In a further aspect, the bell crank rotates with respect to a crank axis that is orthogonal to the installation direction and the longitudinal direction and parallel to the rear card edges of the one or more expansion cards.

In a further aspect, the bell crank comprises a first crank arm and a second crank arm that angular diverge from each other with respect to the crank axis.

In a further aspect, the first crank arm is connected to the pushrod by a pin-and-slot joint and the second crank arm is connected to the movable retainer at a translation joint.

In a further aspect, the movable retainer comprises one or more retainer stanchions configured to adjacently abut the rear card edges of the one or more expansion cards.

The disclosure also provides a computer system comprising a chassis, a motherboard having a planar board format located in the chassis with a board-mounted expansion socket that defines an installation direction, and a riser card assembly. The riser card assembly comprises a card bracket including a card supporting brace and a I/O panel brace at right angles to each other and a riser card attached to the card supporting brace. The riser card has a card contact edge configured for installation in the board-mounted expansion socket in the installation direction. One or more expansion cards have a front I/O edge adjacent to the I/O panel and a rear card edge spaced from the front I/O edge are aligned in a longitudinal direction orthogonal to the installation direction. The riser card assembly comprise a clamping mechanism operatively attached to the card supporting brace which include a pushrod extending in the installation direction and operatively connected to a movable retainer movable along the card supporting brace in the longitudinal direction. The clamping mechanism is operatively configured to move the movable retainer with respect to the rear card edges of the one or more expansion cards upon displacement of the pushrod in the installation direction.

In a further aspect, the clamping mechanism comprises a bell crank operatively connecting the pushrod and the movable retainer and configured for redirecting displacement of the pushrod in the installation direction to movement of the movable retainer in the longitudinal direction.

A possible advantage of the disclosure is that the action of installing the riser card assembly to the motherboard simultaneously actuates the clamping mechanism to clamp the expansion cards to the card bracket of the riser card assembly. The clamping mechanism simultaneously releases the expansion cards upon removing the card assembly from the motherboard. Another possible advantage is that clamping mechanism uses a movable retainer that can be customized to interact with expansion card stacks of different dimensions and different quantities of expansion cards. The movable latch mechanism can adjacently clamp to and hold the rear card edges of the expansion cards, preventing the expansion cards from lifting or separating from the card bracket.

### BRIEF DESCRIPTION OF THE DRAWINGS

FIG. 1 is a perspective view of a computer system including a motherboard that may be connected to a riser card assembly comprised of stacked expansion cards clamped to a card bracket by a clamp mechanism.

FIG. 2 is a partially exploded view of the riser card assembly that includes a card bracket for attaching the riser card and the expansion cards, and that includes a clamping mechanism for holding the expansion cards to the card bracket.

FIG. 3 is a perspective bottom view of a movable retainer that may be included with the clamping mechanism operatively attached to the card bracket.

FIG. 4 is an exploded view of the structural components of the clamping mechanism in relation to the card bracket.

FIG. 5 is top plane view of the card bracket and the clamping mechanism in an unclamped or released state with the movable retainer displaced from the card bracket for illustration.

FIG. 6 is a top plane view of the card bracket and the clamping mechanism in a clamped or engaged state.

FIG. 7 is a perspective view of the riser card assembly positioned for installation to the motherboard and the clamping mechanism separated and disengaged from the expansion board stack.

FIG. 8 is a perspective view of the riser card assembly installed on the motherboard and the clamping mechanism moved longitudinally adjacent to clamp and hold the expansion card stack.

### DETAILED DESCRIPTION

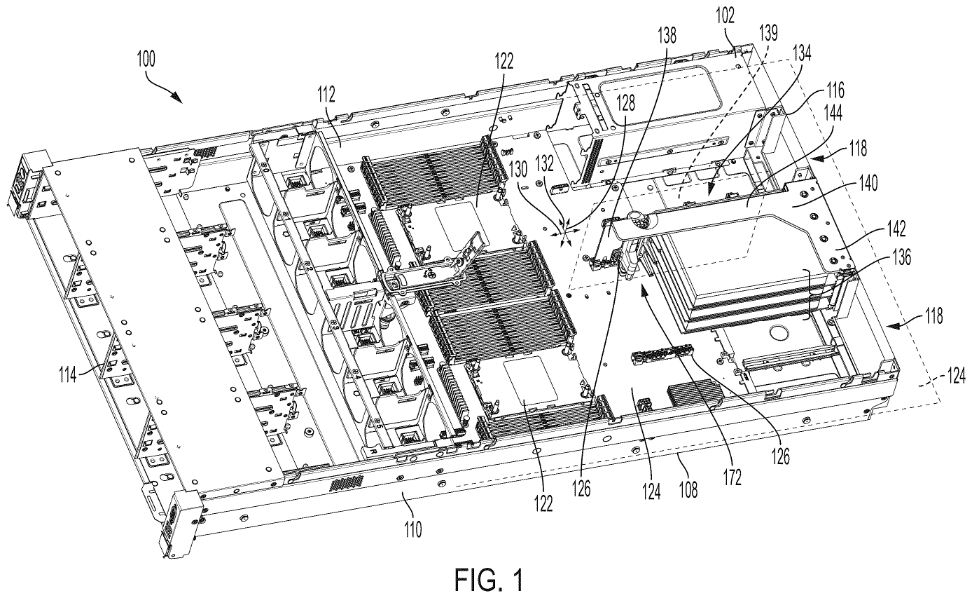

Now referring to the drawings, where whenever possible like reference numbers will refer to like elements, there is illustrated in FIG. 1 a computer system 100 comprised of various electronic devices and hardware that are cooperatively interconnected and assembled together and that may be accommodated in a common computer housing or case referred to as a chassis 102. The chassis 102 can be a box-like structure made of formed sheet metal or molded plastic and that defines an internal space or chassis volume 104 for the internal computer components and electronic hardware of the computer system 100. The computer system 100 can be configured for communicative integration with a larger network or system and the chassis 102 may be designed for mounting into a rack with similar computer network, although in other instances the computer system 100 may be a standalone configuration.

The chassis 102 can accommodate components and hardware devices like central processing units, memory modules, hard drives, power convertors, and fan units for circulating air internally in the chassis volume 104 for cooling of the internal components. The chassis 102 may be box-like and rectangular in shape and can include a planar base panel 108 and first and second upright side panels 110, 112 that extend perpendicularly from the planer base panel 108. To access the internal components in the chassis volume 104, the chassis 102 can include an upright front panel or I/O panel 116 that extends between the first and second upright side panels 110, 112 and which may include a plurality of I/O windows 118 or bays disposed therein. The I/O windows 118 enable the computer system 100 to interface with external cables for networking.

The chassis 102 can also include an upright rear panel 114 located opposite of the I/O panel 118 that may be configured to accommodate various LED indicator lights, activation and setting buttons and switches, ports and sockets for data and power communications, and other features for interfacing with operators and other systems. In the illustrated example, the upright rear panel 114 can include a plurality of fan bays or fan compartments that are intended to accommodate fan modules for drawing airflow into the chassis volume 104. A removable cover may also be included to enclose the chassis volume 104. The chassis panels can be made of formed sheet metal or molded plastic structurally and rigidly connected together to enable the chassis 102 to fixedly support and stabilize the internal hardware components.

To mount and support the electronic devices and computing components, and for electrical connectivity, the chassis 102 can accommodate one or more printed circuit boards located internally in the chassis volume 104. For example, located in the chassis 102 can be a motherboard 120, also referred to as a mainboard or server board, on which one or more processors 122 or central processing units are mounted. The processors 122 can include electronic circuitry configured to conduct logical operations and may be implemented as an integrated circuit or chip. The motherboard 120 can also accommodate other core computing subsystems such as main memory, which may be embodied as a plurality of volatile random access memory modules in a DIMM format.

For surface mounting components onto the motherboard 120, the motherboard can be rigid and have a planar shape with opposing flat surfaces defining a planar form 124. The motherboard 120 can be mounted directly to the base panel 108 of the chassis 102 so that the planar board format 124 is parallel thereto and orthogonal with respect to the first and second upright side panels 110, 112 and the I/O panel 116. The motherboard 120 can be rigidly fixed to the planar base panel 108 by a plurality of standoffs or spacers to provide separation or a gap therebetween for airflow.

For scalability, the computer system 100 can be expandable and provide for the integration of peripheral components and specialized or dedicated sub-systems. To connect with the peripheral systems, the motherboard 120 can include one or more expansion connectors mounted thereon. For example, one or more board-mounted expansion sockets 126 mounted on the planer surface of the motherboard 120 are configured to connect with another printed circuit board in an orthogonal or perpendicular arrangement. To establish the orthogonal arrangement, the board-mounted expansion socket 126 defines an installation direction 128, in which the mating connector is moved for plugging, that is perpendicular to the planar board form 124. In the illustrated environment, the installation direction 128 is aligned parallel with the upright side panels 110, 112 and with the I/O panel 116.

In addition to the installation direction 128, for reference purposes, the chassis 102 can be associated with a lateral direction 132 that extends between the first and second upright side panels 110, 112 and a longitudinal direction 130 that extends between the upright rear panel 114 and the I/O panel 116. The planar board format 124 of the motherboard 120 can be situated in the plane defined by the lateral and longitudinal directions 130, 132. To direct the expansion cards toward the I/O windows 118, the board-mounted expansion socket 126 can include an elongated socket slot extending in the longitudinal direction 130.

The board-mounted expansion socket 126 can be embodied as an edge connector that includes a socket slot disposed in an elongated insulative housing and that can receive the edge of the printed circuit card. The insulative housing of the edge connector includes spring-loaded contacts that bias against corresponding conductive traces on the planar surfaces at the edge of the printed circuit card, referred to a gold finger contacts, to established electronic communication between the components. When the printed circuit card, designated an expansion card or add-in card, is plugged into the board-mounted expansion socket 126, the card can extend perpendicularly to the planar board form 124 and can be directed toward the I/O panel 118.

In a computer system 100 that is expandable, such as a storage server or an application server, the number of expansion cards required may exceed the number of board-mounted expansion sockets 126 on the motherboard 120. To connect a plurality of expansion cards in common to a board-mounted expansion socket 126, the plurality of expansion cards can be bundled together into a riser card assembly 134. For example, the riser card assembly 134 can include an expansion card stack 136 that can be comprised of several individual expansion cards arranged horizontally in the chassis 102. The expansion card stack 136 made up of multiple expansion cards is connected to a single riser card 138 that, in turn, is connected vertically to the board-mounted expansion socket 126. The riser card 138 can be a printed circuit board having a planar, rectangular shape that defines a planar card format 139.

The riser card assembly 134 is located adjacent to the I/O panel 118 in the longitudinal direction 130 and the expansion card stack 136 is arranged and stacked vertically in the installation direction 128. The riser card 138, which the expansion cards are commonly connected to, is arranged perpendicular to the planar board format 124 and extends in the installation direction 128. To physically retain the expansion card stack 136 to the riser card 138, the riser card assembly 134 can include a card bracket 140 that may be formed as a structural angle that is shaped as an L. The card bracket 140 can also functions to fixate the orientation of the expansion card stack 136 and the riser card 138 with respect to the forward I/O panel 116 and the motherboard 124.

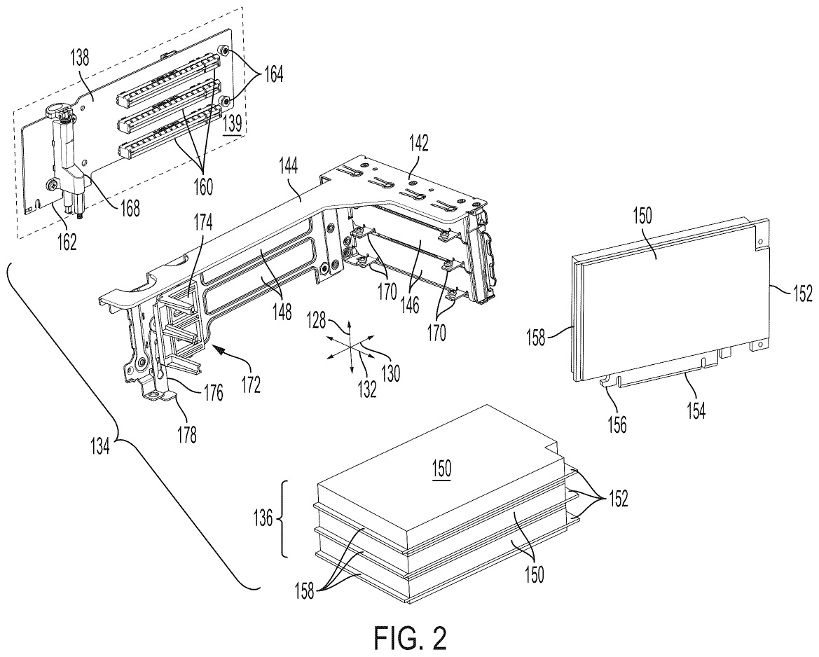

Referring to FIG. 2, the card bracket 140, which is shaped as structural angle, can include a first leg, referred to as a I/O panel brace 142 and a second leg, referred to as a card supporting brace 144, that intersect at right angles. When installed in the chassis, the I/O panel brace 142 can align with the lateral direction 132 and the card supporting brace 144 can align with the longitudinal direction 130. To accessibly interface with the I/O windows in the I/O panel, the I/O panel brace 142 can include one or more I/O access slots 146 or cutouts that are parallel to each other in the installation direction 128 and aligned with the lateral direction 132.

To enable the expansion cards and riser card to interface, the card supporting brace 144 can include a plurality of card access slots 148 that are also arranged parallel in the installation direction 128 and extend in the longitudinal direction 130. To accommodate expansion card stacks 136 of varying heights, and thus varying numbers of expansion cards, the card supporting bracket 144 can be a flat planar plate of suitable length and width. The card bracket 140 can be made of formed and pressed sheet metal or molded plastic, and the perpendicularly intersecting I/O panel brace 142 and card supporting brace 144 can be integrally connected or can be separate pieces joined together by threaded fasteners such as sheet metal screws.

The expansion card stack 136, which can be accommodated in the card bracket 140, can include a plurality of expansion cards 150 that are planar and rigid printed circuit boards and that may be rectangular in shape. The expansion cards 150 can have a front I/O edge 152 and a lower contact edge 154. Mounted along the front I/O edge 152 can be communication ports or socket jacks to connect with external communications cables for networking. Located along the lower contact edge 154 can be conductive traces or gold fingers that can create electrical contacts when the expansion card 150 is inserted into the slot of the edge connector. Also formed along the lower contact edge 154 can be a card hook 156 oriented rearward in the longitudinal direction 130 as per convention in the design of expansion and add-in cards. Located parallel to the front I/O edge 152 can be a rear card edge 158 which is spaced apart in the longitudinal direction 130. An upper card edge may extend between the front I/O edge 152 and rear card edge 158 to complete the rectangular shape, although the expansion cards 150 may have different configurations, such as irregular polygonal shapes.

For networking, the expansion cards 150 may be configured as peripheral component interface (PCI) cards able to communicate with the processors through the motherboard via a PCI communications bus. The PCI cards may be network interface cards having communication ports and communication jacks to interface with external systems. In another example, the expansion card 150 can include one more graphics processing units (GPUs) that are designed for applications such as image processing, data analytics, artificial intelligence, and other high-performance computing applications. In a further example, the expansion cards 150 can be associated with additional data storage such as hard disk drives or solid state drives.

To physically and electrically connect with the plurality of expansion card 150 in the expansion card stack 136, the riser card 138 can include a corresponding plurality of card-mounted expansion sockets 160. The card-mounted expansion sockets 170 can be perpendicular or right-angled edge connectors that are mounted to a surface of the planar card format 139 of the riser card 138. The card-mounted expansion sockets 160 can include elongated slots aligned in the longitudinal direction 130 which the lower contact edges 154 of the expansion cards 150 can be inserted. The expansion cards 150 are moved in the lateral direction 132 for insertion and installation into the card-mounted expansion sockets 160.

To physically and electrically connect to the motherboard, the riser card 138 can include a riser contact edge 162 on which can be located conductive traces or gold fingers. The riser contact edge 162 can extend in the longitudinal direction 130 and can be oriented for installation with the installation direction 128. The riser card 138 can be planar and rectangular in shape, although in other embodiments, the riser card 138 can have other configurations.

To fixedly attach the riser card 138 to the card supporting brace 144 of the card bracket 140, the riser card can include threaded standoffs 164 or spacers that are mounted to the planar face and perpendicular to the planar card format 139. When the riser card 138 is attached to the card supporting brace 144, the card-mounted expansion sockets 160 align with the card access slots 148 and can connect through the card access slots to the expansion cards 160. To fixedly attach the riser card assembly 134 to the motherboard, the riser card 138 can have guiding and locking components 166 that are mounted to the planar card format 139 and oriented downwardly in the installation direction 128.

To securely fix the plurality of expansion cards 150 to the card bracket 140, the I/O panel brace 142 can include one or more attachment tabs 170 that are bent in the longitudinal direction 130. Threaded fasteners can be inserted through the attachment tabs 170 and into corresponding apertures along the front I/O edge 152 to fix the expansion card 150 to the I/O panel brace 142. Fastening each of the expansion cards 150 to attachment tabs 170 aligns and secures the front I/O edges 152 with respect to the I/O panel brace 142 and stabilizes and prevents separation of the expansion card stack 136 and the card bracket 140.

To support and stabilized the expansion card stack 136 at the rear card edge 158 of the expansion cards 150, the card bracket 140 can include a clamping mechanism 172. The clamping mechanism 172 can be operatively attached to the card supporting brace 144 and can be configured to produce and apply a clamping force in the longitudinal direction 130. The generated clamping force produced by the clamping mechanism 172 is applied against the rear card edges 158 thereby holding the riser card stack 136 firmly against the front I/O panel brace 142 of the card bracket 140. Furthermore, the clamping mechanism 172 can be configured for actuation concurrently during installation of the riser card assembly 134, which is achieved by inserting the riser contact edge 162 of the riser card 138 into the board-mounted expansion socket of the motherboard.

To apply the clamping force in the longitudinal direction 130, the clamping mechanism 172 can include a movable retainer 174 that is operatively attached to and arranged to move along the card supporting brace 144. The movable retainer 174 can be located on the planer surface of the card supporting brace 144 opposite of the riser card 138 and can extend along in the lateral direction 132 to align with the rear card edges 158 of the plurality of expansion cards 150. The movable retainer 174 is located longitudinally rearward of the expansion card stack 136 and can reciprocally move in the longitudinal direction 130 to abut against the rear card edges 158. To translate the moveable retainer in the longitudinal direction 130, the clamping mechanism 172 includes structural components that cooperate to redirect and apply forces produced during installation of the riser card assembly to the motherboard.

For example, to cause movement of the movable retainer 174, the clamping mechanism 172 includes a pushrod 176 that is also operatively attached to the card supporting brace 144. The pushrod 176 is oriented in the installation direction 128 and can be movably driven and displaced with respect to the card bracket 140 when the riser card assembly 134 is placed adjacent to the motherboard. To initiate contact with the motherboard, a contact foot 178 is formed at the end of the pushrod 176 and that extends beyond the lower edge of the card supporting brace 144.

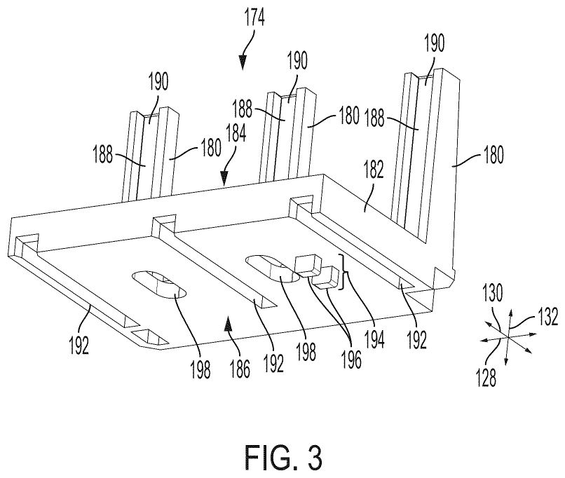

Referring to FIG. 3, to physically contact the rear card edges of the plurality of expansion cards, the movable retainer 174 can include a corresponding number of retainer stanchions 180 that project from the retainer base 182. For example, the retainer base 182 can be a flat, monolithic structural block defined by parallel upper and lower, or top and bottom base surface 184, 186. The retainer stanchions 180 can extend from an edge of the top base surface 184 as columns or pedestals. The retainer stanchions 180 can be parallel to each other and spaced apart to make abutting contact with individual expansion cards. The number and pitch of the retainer stanchions can correspond to the arrangement of expansion cards in the expansion card stack 136. The movable retainer can be made from cast metal or molded thermoplastic.

To couple with the expansion cards, the retainer stanchions 180 can include card receiving grooves 188 formed as three-sided channels therein that are sized to receive the rear card edges. The card receiving grooves 188 can be linear and extend the length of the retainer stations 180 with respect to the installation direction 128. To cushion or soften contact with the rear card edges, strips of rubber or elastomer 190 may be attached to the retainer stanchions 180 inside the card receiving grooves 188.

Disposed on the bottom base surface 186 of the retainer base 182, opposite of the retainer stanchions 180, can be a plurality of hook grooves 192 formed as three-sided channels in parallel for receiving the card hooks 156 extending from the lower contact edges of the expansion cards. The hook grooves 192 can be arranged to assist in aligning the expansion cards with respect to the longitudinal direction 130. Also formed on the bottom base surface 186 of the retainer base 182 can be a bifurcated catch 194 that includes a pair of protrusions 196 that are spaced apart and parallel to each other. The bifurcated catch 194 can receive and restrain a corresponding structure between the pair of protrusions 196 for the transfer of motive force.

To align and guide movement of the movable retainer 174, the retainer base 182 includes a pair of retainer slots 198 disposed between the top and bottom base surfaces 184, 186. The retainer slots 198 can be oblong ovals and can be elongated with respect to the longitudinal direction 130. The retainer slots 198 are sized to receive pins or similar structures that can moveably oscillate with respect to the longitudinal direction 130. The retainer slots 198 can also be parallel and spaced apart in the installation direction 128 to constrain and direct movement of the movable retainer 172 in the longitudinal direction 130.

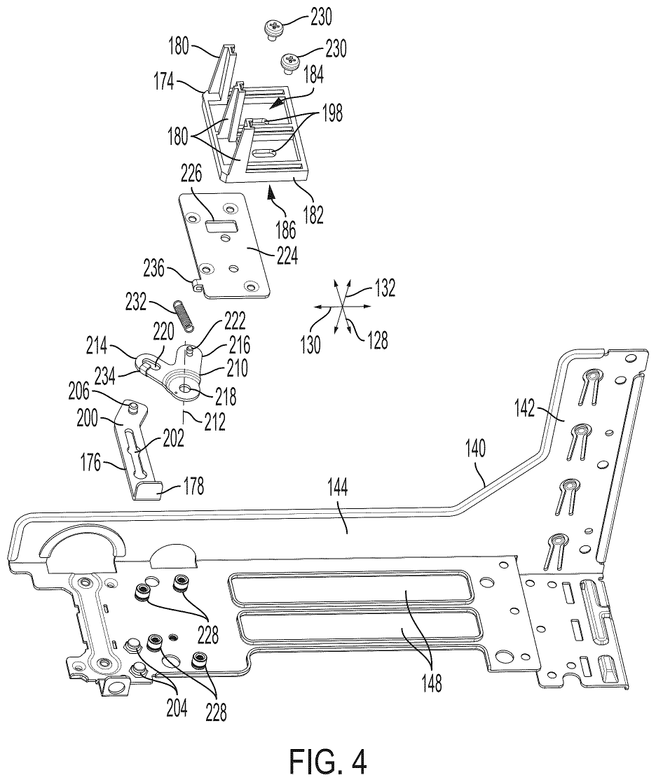

Referring to FIG. 4, the structural parts of the clamping mechanism 172 are arranged to redirect the forces applied to displace the pushrod 176 to direct linear translation of the movable retainer 172 with respect to the longitudinal direction 130. The pushrod 176 can be a flat bar stock 200 formed of a metal bar with the contact foot 178 bent in the flat bar stock at a right angle. Located on the opposite end of the flat bar stock 200 from the contact foot 178, the pushrod 176 can include a pushrod pin 206 protruding in the lateral direction 132. The pushrod 176 can be attached for linearly displacement with respect to the card supporting brace 144 in the installation direction 128.

To moveably attach the pushrod 176 to the card supporting brace 144, a pushrod guide slot 202 is cut lengthwise into the flat bar stock. A pair of pushrod guide pins 204 can be mounted to the card supporting brace 144 to protrude in the lateral direction 132 perpendicular to the installation direction 128. The pushrod guide slot 202 is shaped and sized to receive the guide pins 204 and form a pin-and-slot joint that allows linear movement of the pushrod 176 in the installation direction 128 in response to a displacement force applied to the contact foot 178.

To redirect linear movement of the pushrod 176, a bell crank 210 is pivotally attached to the card supporting brace 144 to rotate about a crank axis 212. The bell crank 210 can be a stamped structure of metal that functions as a bent lever with two offset contact points that tilt in relation to each other. For example, the bell crank 210 can include a first crank arm 214 and a second crank arm 216 that extend radially from a crank joint 218, which may be a revolute pin joint that corresponds in location to crank axis 212. The first crank arm 214 and the second crank arm 216 are angularly spaced apart with respect to the crank axis 212 and diverge from each other in relation to the crank joint 218. When the bell crank 210 is pivotally attached to the card supporting brace 144, the crank axis 212 defined by the crank joint 218 aligns with the lateral direction 132. The bell crank 210 may have other structural shapes than as illustrated, such as a curved rocker arm or other suitable configurations.

To connect with the pushrod 176, a crank slot 220 is disposed into the first crank arm 214. The crank slot 220 is designed to receive the pushrod pin 206 to form another pin-and-slot joint linking the pushrod 176 and the bell crank 210. The location of the pushrod pin 206 and the crank slot 220 may be reversed and still establish as pin-and-slot joint converting axial movement of the pushrod 176 to rotation of the bell crank 210. A crank pin 222 can be located on and protrude from the second crank arm 216 in a direction offset from and parallel with the crank axis 212. When a force is applied to the first crank arm 214 through the crank slot 220, the bell crank 210 pivots at the crank joint 218 about the crank axis 212 tilting the second crank arm 216 to move the crank pin 222 in a different direction.

When the bell crank 210 is rotatably attached to the card supporting brace 144 at the crank joint 218, the direction of motion of the crank pin 222 aligns with the longitudinal direction 130. To transfer the linear forces directed in the longitudinal direction 130 from the second crank arm 216 to the movable retainer 174, the crank pin 222 form part of a translation joint with the bifurcated catch 194 to convert rotation of the bell crank 210 to linear movement of the movable retainer. The translation joint is able to convert the curvilinear motion of the pivoting second crank arm 216 about the crank axis 212 to linear translation of the movable retain 174 in the longitudinal direction 130.

For example, the crank pin 222 can be retained in the bifurcated catch 194 is formed on the bottom base surface 186 shown in FIG. 3. For example, the crank pin 222 can be received between the pair of protrusions 196 to allow for respective rotation while transferring force and load between the bell crank 210 and the movable retainer 174. In other examples, different structural attachments, such as dowl pins, can link the bell crank 210 and movable retainer 174 and function as the translation joint.

To fix the components in spatial relation, the clamping mechanism 172 can include a frame plate 224 that attaches to the card supporting brace 144. The frame plate 224 can be stamped metal plate that is planar and rectangular in shape and can be situated between the bell crank 210 and the retainer base 182 of the movable retainer 174. To connectively link the bell crank 210 and movable retainer 174, the frame plate 224 can include a plate slot 226 cut into rectangular shape through which the crank pin 222 can pass. The plate slot 226 can be elongated to allow linear movement of the crank pin 222 in the longitudinal direction 130.

To attach the frame plate 224 to the card supporting brace 144, a plurality of apertures can be disposed in the frame plate that receive fasteners that fasten to a corresponding threaded protrusions 228 on the card supporting brace 144. Fastening the frame plate 224 to the threaded protrusion 228 fixes the frame plate 224 in relation to the card supporting brace 144. The frame plate 224 can partly cover and protect the moving structural parts of the clamp mechanism 172 including the bell crank 210 pivotally joined to the card supporting brace 144 at the crank joint 218. When the frame plate 224 is attached to the card supporting brace 144, the two planar structures may be parallel to each other and the frame plate 224 may be perpendicular to the crank axis 212 established by the crank joint 218 of the bell crank 210.

To attach the movable retainer 174 to the frame plate 224, a pair of retainer fasteners 230 can be inserted through the corresponding pair of retainer slots 198 in the retainer base 184. The pair of retainer fasteners 230 can fasten to a pair of corresponding threaded apertures on the frame plate 224. Because the frame plate 224 is fixedly attached to the card supporting brace 144 of the card bracket 140, the retainer fasteners 230 are indirectly fixed in relation to the card bracket 140. When the movable retainer 174 is adjacent to the frame plate 224, the plurality of retainer stanchions 180 extend laterally parallel with the crank axis 212 associated with the bell crank 210.

The retainer fasteners 230 and the retainer slots 198 form another pin-and-slot joint in which the retainer fasteners are capable of moving linearly relative to the oblong shape of the retainer slots 198. Because the retainer fasteners 230 are fixed to the frame plate 224, which is fixed to the card supporting brace 144, the movable retainer 174 is able to translate in the longitudinal direction 130 relative to the card bracket 140.

In an embodiment, the clamping mechanism 172 can be spring-loaded and configured to return and hold the movable retainer 174 in a desired position with respect to the longitudinal direction 130, for example, rearward and separated from the expansion card stack. For example, the clamping mechanism 172 may include a coil spring 232, which may be produced from a helically wound coil of spring steel and which can expand and contract along a spring axis when under tension or compression. The coil spring 232 can be operatively connected between the bell crank 210 and the frame plate 224 biasing them into relative desired positions.

To attach the coil spring 232, the first crank arm 214 can include first spring hook 234 that is located toward the distal end adjacent to the crank slot 220. The frame plate 224 can include a second spring hook 236 that is formed along the edge of the rectangular periphery of the frame plate 224. When attached between the first and second spring hooks 234, 236, the coil spring 232 contracts to pull the first crank arm 214 relative to the frame plate 224. Likewise, when the bell crank 210 rotates to move the movable retainer 174 longitudinally, the coil spring 232 is tensioned and stretched. Relative movement between the structural parts is possible because the bell cranks is pivotally attached to the card supporting brace 144 and the frame plate 224 is fixed in positional relation to the card supporting brace 144.

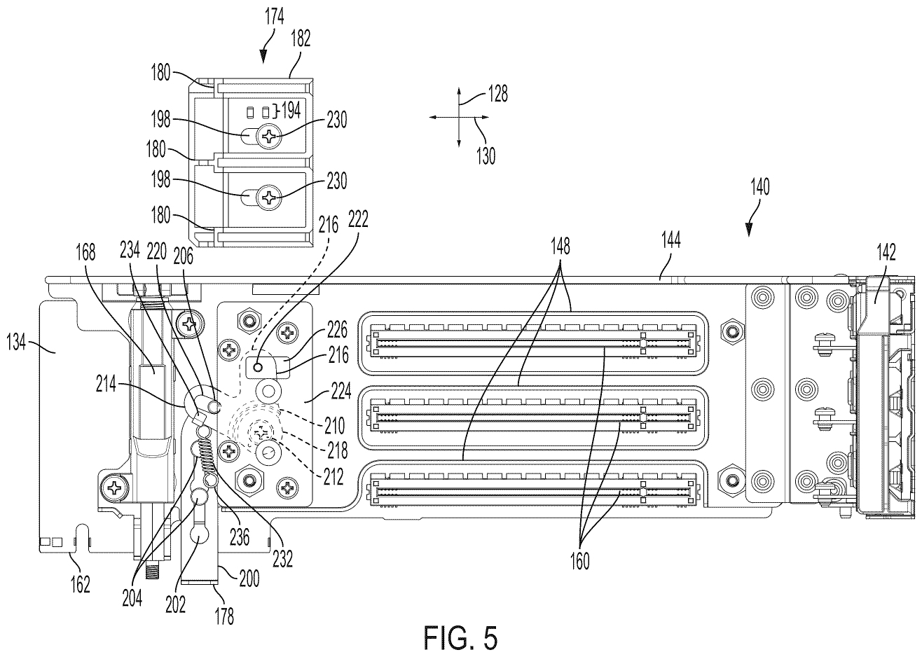

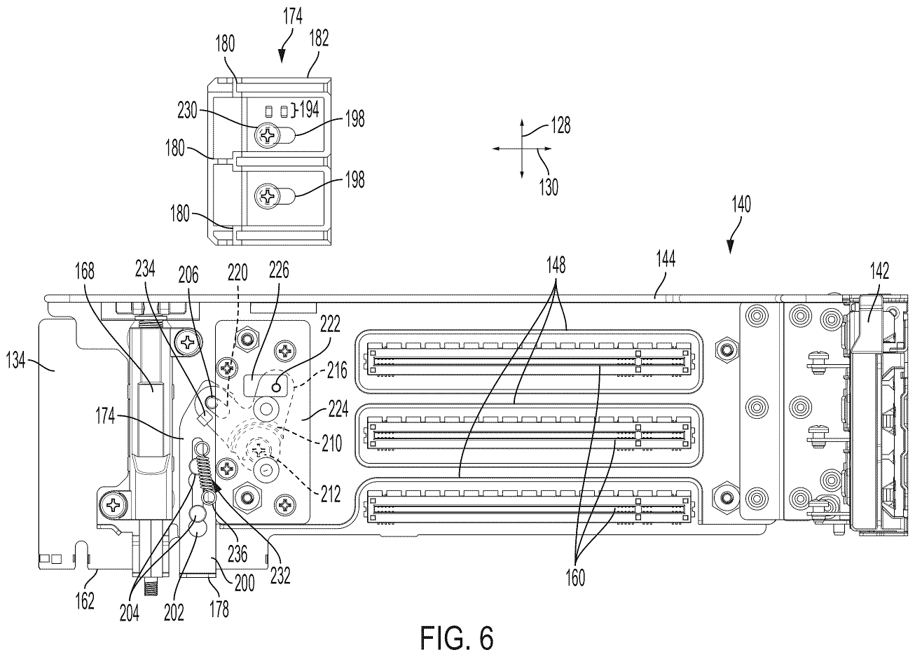

Referring to FIGS. 5 and 6, actuation and release of the clamping mechanism 172 is caused by placement or removal of the riser card assembly adjacent to the motherboard 120, for example, when connecting to the board-mounted expansion sockets. Referring to FIG. 5, the clamping mechanism 172 can be normally biased into the release state or position by the action of the coil spring 232. The coil spring 232 attached between the bell crank 210 and the frame plate 224 can contract in length under the stored spring energy, thereby drawing the first crank arm 214 of the bell crank 210 downward in the installation direction 128. The bell crank 210 is thus caused to rotate about the crank axis 212 at the crank joint 218.

Pivoting movement to the first crank arm 214 currently applies displacement forces to the pushrod 176 through the pin-and-slot joint formed between the crank slot 220 in the first crank arm 214 and the pushrod pin 206 protruding from the pushrod 176. The pushrod 176 is moved or displaced linearly in the installation direction 128 relative to the card supporting bracket 144, which the pushrod 176 is operatively attached to by the pin-and-slot joint formed between the pushrod guide slot 202 and the guide pins 204 slidably located therein. The pushrod 176 is linearly moved in the installation direction 128 such that the contact foot 178 is positioned beyond the riser contact edge 162 of the riser card 138. The contact foot 178 is exposed to make abutting contact with the motherboard 120 in the installation direction 128.

Also in the released position shown in FIG. 5, rotation of the bell crank 210 about the crank axis pivots the second crank arm 216 rearwardly in the longitudinal direction 130. The crank pin 222 that projects from the second crank arm 216 moves longitudinally rearward in the plate slot 226. Reward movement of the crank pin 222 also causes rearward movement of the movable retainer 174, to which the crank pin 222 is attached by engagement with the bifurcated catch 194 on the underside of the retainer base 182. The retainer fastener 230 can be situated longitudinal forwardly in the oblong shape of the retainer slots 198 of the retainer base 182.

Referring to FIG. 6, when the card bracket 140 is moved adjacent to the motherboard 120, the contact foot 178 of the pushrod 176 abuts the planar surface of the motherboard and the pushrod is displaced linearly upward in the installation direction 128 relative to the card supporting brace 144. For example, the pushrod guide slot 202 allows the guide pins 206 fixed to the card supporting brace 144 to move linearly downwards with respect to the axis of the pushrod 176. The contact foot 178 may move into coextensive alignment with riser contact edge 162 in the installation direction 128.

Linear displacement of the pushrod 176 in the installation direction 128 currently pivots the first crank arm 214 through operation of the pin-and-slot joint formed between the pushrod pin 206 and the crank slot 220. Pivoting of the first crank arm 214 rotates the bell crank about the crank axis 212 at the crank joint 218 thereby pivoting the second crank arm 216 forwardly in the longitudinal direction 130. Pivoting of the first crank arm 214 also stretches the coil spring 232 attached to the frame plate 224.

Pivotal movement of the second crank arm 216 also moves the crank pin 222 linearly in the longitudinal direction with respect to the plate slot 226. The oblong shape of the plate slots 226, in particular, allows for linear movement of the crank pin 222. The crank pin 222 also imparts linear movement in the longitudinal direction 128 to the movable retainer 174 through translation joint formed with the bifurcated catch 194 on the retainer base 182 to which the crank pin 222 is retained. The movable retainer 174 is able to move with respect to the frame plate 224 fixed to the card supporting brace 144 by relative movement of the retainer fasteners 230 with respect to the retainer slots 198 in the retainer base 182. The bell crank 210 therefore redirects linear displacement in the installation direction, due to installation of the riser card assembly to the motherboard 120, to a clamping force applied in the longitudinal direction 130 through the movable retainer 174. The movable retainer 174 is caused to translate with respect to the card supporting brace 144 in the longitudinal direction 130. As shown in FIG. 6, the retainer fasteners 230 are situate at the other oblong end of the retainer slots 198 due to relative motion between the movable retainer 174 and the card supporting brace 144.

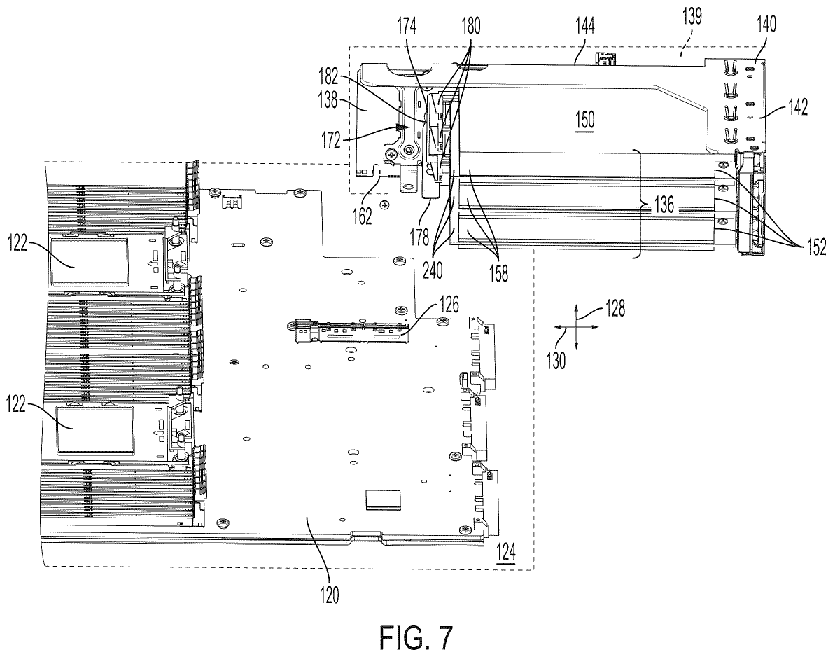

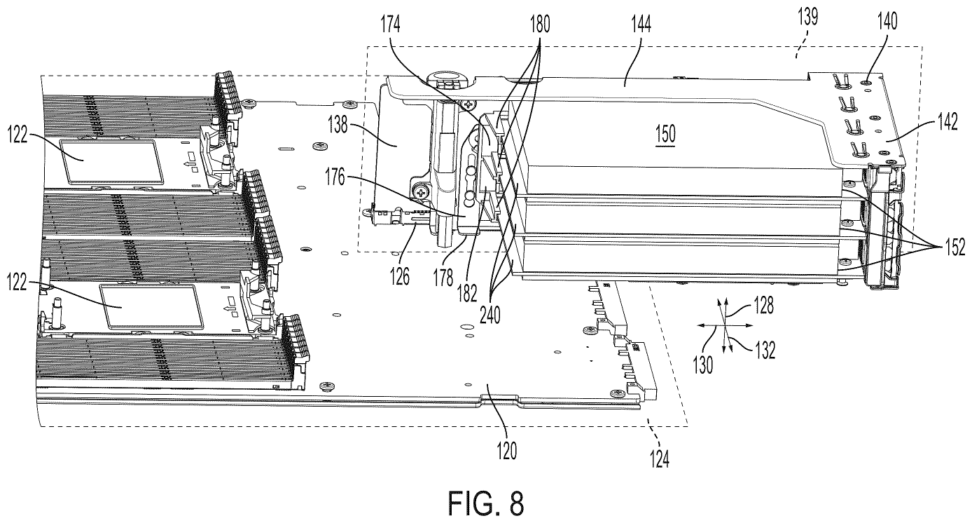

Referring to FIGS. 7 and 8, the configuration of the clamping mechanism 172 in causing movement of the movable retainer 174 applies and releases a clamping force in the longitudinal direction 130 that can assist in holding the plurality of expansion cards 150 securely to the card bracket 140. Referring to FIG. 7, when the riser card assembly 134 is separate from the motherboard 120, for example, prior to installation in the chassis 102, the spring-loaded clamping mechanism 172 is in a released position under the biasing action of the coil spring. The pushrod 176 is displaced downwardly in the installation direction 128 and the contact foot 178 extends beyond the riser contact edge 162 and is directed toward the motherboard 120. The movable retainer 174 is also separated and space from the expansion card stack 136 in the longitudinal direction 130.

Referring to FIG. 8, during installation of the riser card assembly 134 to the board-mounted expansion socket 126, the contact foot 178 of the pushrod 176 abuts against the mother board 120 and is displaced in the installation direction 128. The biasing force of the coil spring is overcome and the clamping mechanism 172 operates to move the movable retainer 174 toward the rear card edges 158 of the plurality of expansion cards 150 exposed in the expansion card stack 136. For example, the retainer stanchions 180, which extend in the lateral direction 132, can move into adjacent contact with the rear card edges 158 of the expansion cards 150. The clamping force is therefore applied in the longitudinal direction 130 between the movable retainer 174 and the expansion card stack 136 retaining and holding the individual expansion cards 150 at the rear card edges 158 to the card bracket 140.

When the moveable retainer is moved longitudinally adjacent to the expansion card stack 136, the card hooks 156 located on the lower card edge 154 can be received in the plurality of hook grooves 192 on the bottom surface 186 of the retainer base 182. The card hooks 156 locked in the hook groove 192 further assist in holding the expansion cards 150 to the card bracket 140. The card hooks 156 particularly prevent the rear card edges 158 from separating from the card supporting brace 144 in the lateral direction 132. If desired, the riser card assembly 134 can be further secured by fastening the card bracket 140 to the motherboard 120.

In an example, to assist in holding the rear card edges 158 to the retainer stanchions 180 extending from the movable retainer 174, the expansion cards 150 can be associated with a card retention tail 240. The card retention tails 240 can be structural features that projects longitudinal rearward of the expansion card stack 136 for accessibility and that extend adjacently along the rear card edge 158 in the lateral direction 132. The card retention tails 240 can be sized to fit into the card receiving grooves 188 on the retainer stanchions 180.

In an embodiment, the card retention tail 240 can be a strip or sheet of elastomeric material having a compressible characteristic. The card retention tail 240 can be attached along the rear card edge 158 or can be a planar sheet of material positioned between the two adjacent expansion cards 150 in the expansion card stack 136. When the movable retainer 174 is moved longitudinally adjacent to the rear card edges 158, the retention stanchions 180 can contact and compress the card retention tails 180 holding the expansion cards 150 to the card bracket 140. Use of the compressible or elastomeric material for the card retention tails 240 mitigates possible damage due to abutting contact between the movable retainer 174 and the expansion card stack 136. The resilient characteristics of the card retention tail 240, and the strips of rubber or elastomer 190 located in the card receiving grooves 188 if included, also assists in releasing the retainer stanchions from the rear card edges 158 when the movable retainer 174 and the expansion card stack 136 are longitudinally moved apart.

To remove expansion cards 150 from the expansion card stack 136, for example, during an upgrade, the riser card assembly 134 is lifted in the installation direction 128 and separate from the motherboard 120. The riser contact edge 162 of the riser card 138 is consequently removed from the board-mounted expansion socket 126. Also, the contact foot 178 of the pushrod 176 is released and can extend in the installation direction 128 under the biasing action of the coil spring 232. The movable retainer 174 is also retracted from the expansion card stack 136 in the longitudinal direction 130 separating the retainer stanchions 180 from the rear card edges 158 of the expansion cards 150, which can be detached and removed from the riser card assembly 136.

The two retainer fasteners 230 that extend through the retainer slots 198 of the retainer base 182 assist in directing translational movement of the movable retainer 174 in the longitudinal direction 130. For example, the parallel and spaced apart arrangement of the retainer slots 198 and the retainer fasteners 230 prevent the movable retainer 174 from pivoting or twisting. The plurality of retainer stanchions 180 simultaneously contact the rear card edges 158 of the corresponding plurality of expansion cards 150.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A riser card assembly for installation in a computer system comprising:
a card bracket comprising an I/O panel brace and a card supporting brace intersecting at a right angle;
an expansion card stack comprising one or more expansion cards, each expansion card having a front I/O edge adjacent to the I/O panel brace and a rear card edge spaced apart from the front I/O edge in longitudinal direction; and
a clamping mechanism operatively attached to the card supporting brace, the clamping mechanism comprising a pushrod extending beyond the card bracket in an installation direction of the riser card assembly and a movable retainer configured to move in the longitudinal direction adjacent to the rear card edges upon displacement of the pushrod in the installation direction.

2. The riser card assembly of claim 1, wherein the longitudinal direction and the installation direction are orthogonal.

3. The riser card assembly of claim 2, wherein the clamping mechanism comprises a bell crank for redirecting displacement of the pushrod in the installation direction to movement of the movable retainer in the longitudinal direction.

4. The riser card assembly of claim 3, wherein the clamping mechanism is spring-loaded and comprises a coil spring biasing the bell crank to move the movable retainer longitudinally away from the rear card edges of the expansion card.

5. The riser card assembly of claim 3, wherein the bell crank is rotatably attached to the card supporting brace to rotate with respect to a crank axis that is orthogonal to the installation direction and the longitudinal direction.

6. The riser card assembly of claim 5, wherein the bell crank comprises a first crank arm and a second crank arm that angularly diverge from each other with respect to the crank axis.

7. The riser card assembly of claim 6, wherein the first crank arm is connected to the pushrod by a pin-and-slot joint.

8. The riser card assembly of claim 6, wherein the second crank arm is connected to the movable retainer by a translating joint.

9. The riser card assembly of claim 8, wherein the translating joint comprises a crank pin on the second crank arm that can be retained in a bifurcated catch on the movable retainer.

10. The riser card assembly of claim 5, wherein the clamping mechanism comprises a frame plate fixedly attached to the card supporting brace such that the movable retainer moves with respect to the frame plate.

11. The riser card assembly of claims 10, wherein the crank axis is perpendicular to the frame plate.

12. The riser card assembly of claim 5, wherein the movable retainer comprises one or more retainer stanchions that extend from a retainer base in a lateral direction parallel to the crank axis.

13. The riser card assembly of claim 12, wherein the one or more expansion cards are each associated with a card retention tail that is configured to releasably engage with a respective one of the retainer stanchion.

14. A method of installing a riser card assembly into a computer system comprising:
providing a card bracket having a card supporting brace extending in a longitudinal direction;
attaching a riser card to the card supporting brace, the riser card comprising a riser contact edge directed in an installation direction orthogonal to the longitudinal direction;
connecting one or more expansion cards to the riser card, the one or more expansion cards each comprising a rear card edge oriented orthogonal to the longitudinal direction and to the installation direction;
installing the riser contact edge into a board-mounted expansion socket mounted on a motherboard by moving the riser card assembly in the installation direction; and
linearly displacing a pushrod in the installation direction during installation in the board-mounted expansion socket, the pushrod operatively connected through a bell crank to linearly move a movable retainer in the longitudinal direction with respect to the card supporting brace and adjacent to the rear card edge of the one or more expansion cards.

15. The method of claim 14, wherein the bell crank rotates with respect to a crank axis that is orthogonal to the installation direction and the longitudinal direction and parallel to the rear card edges of the one or more expansion cards.

16. The method of claim 15, wherein the bell crank comprises a first crank arm and a second crank arm that angular diverge from each other with respect to the crank axis.

17. The method of claim 16, wherein the first crank arm is connected to the pushrod by a pin-and-slot joint and the second crank arm is connected to the movable retainer at a translation joint.

18. The method of claim 14, wherein the movable retainer comprises one or more retainer stanchions configured to adjacently abut the rear card edges of the one or more expansion cards.

19. A computer system comprising:
a chassis;
a motherboard having a planar board format located in the chassis and comprising a board-mounted expansion socket that defines an installation direction;
a riser card assembly comprising:
a card bracket comprising a card supporting brace and a I/O panel brace at right angles to each other;
a riser card attached to the card supporting brace; the riser card having a card contact edge configured for installation in the board-mounted expansion socket in the installation direction;
one or more expansion cards comprising a front I/O edge adjacent to the I/O panel and a rear card edge spaced from the front I/O edge in a longitudinal direction orthogonal to the installation direction;
a clamping mechanism operatively attached to the card supporting brace; the clamping mechanism comprising a pushrod extending in the installation direction and operatively connected to a movable retainer movable along the card supporting brace in the longitudinal direction;
wherein the clamping mechanism is operatively configured to move the movable retainer with respect to the rear card edges of the one or more expansion cards upon displacement of the pushrod in the installation direction.

20. The computer system of claim 19, wherein the clamping mechanism comprises a bell crank operatively connecting the pushrod and the movable retainer and configured for redirecting displacement of the pushrod in the installation direction to movement of the movable retainer in the longitudinal direction.
